(19) United States
(12) Patent Application Publication
(10) Pub. No.: US 2019/0343024 A1
(43) Pub. Date: Nov. 7, 2019

(54) MINI-SPLIT HVAC DUCTED RETURN AND SUPPLY SYSTEM

(71) Applicant: DCIM Solutions, LLC, Glassboro, NJ (US)

(72) Inventors: Andrew Graham, Spicewood, NJ (US); Peter Grant Graham, High Bridge, NJ (US)

(73) Assignee: DCIM Solutions, LLC, Glassboro, NJ (US)

(21) Appl. No.: 16/400,950

(22) Filed: May 1, 2019

Related U.S. Application Data
(60) Provisional application No. 62/665,260, filed on May 1, 2018.

(51) Int. Cl. H05K 7/20

(52) U.S. Cl. CPC H05K 7/20745

(57) ABSTRACT

Improved methods and systems for cooling a data room are presented wherein an HVAC mini-split unit is configured with a manifold and return air ducts that enhance the movement of warm air to the return air intake of the unit without mixing the return air with the cool air supplied by the unit. Other embodiments provide methods and systems for supplying cool air from a mini-split unit to the front of the equipment rack, thereby shortening the path of warm air behind the equipment rack to the mini-split unit and eliminating the mixing of intake air with supply air.

### PRIORITY STATEMENT UNDER 35 U.S.C. § 119 & 37 C.F.R. § 1.78

This non-provisional application claims priority based upon prior U.S. Provisional Patent Application Ser. No. 62/665,260 filed May 1, 2018 in the names of Andrew Graham and Peter Grant Graham entitled “MINI-SPLIT HVAC DUCTED RETURN AND SUPPLY SYSTEM,” the disclosures of which are incorporated herein in their entirety by reference as if fully set forth herein.

### BACKGROUND OF THE INVENTION

Computer data centers vary widely in terms of facility construction, space design, electrical and mechanical configurations, etc. However, because the equipment located in data centers, including servers, communication gear, and storage equipment, generates significant amounts of heat, there is a need to efficiently remove the heat generated in the data center. In fact, heat that is constantly generated by the electronic equipment inside the data center makes cooling the data room one of the biggest challenges in data center operations.

The primary function of any data center cooling system is to remove the heat generated by the equipment to prevent overheating, which could lead to costly downtime. A continuous supply of cool air will allow the electronic equipment to reduce internal fan speeds and overall power consumption. An efficient cooling system is, therefore, a critical aspect in ensuring the safety of equipment and the delivery of smooth data center operation. Ensuring an effective cooling infrastructure for a data center begins with finding the right air conditioning system. The system must not only be capable of providing sufficient cooling temperature, but also versatile enough to work in a unique environment with unique cooling requirements like a data center.

### SUMMARY OF THE INVENTION

An HVAC mini-split unit is positioned on the back side of electronic equipment and is configured with a manifold that mounts to the mini-split unit. One or more return air ducts having proximal ends that connect to the manifold and distal ends that extend into the data room are attached to the manifold. Cool air flows downward from the unit and cools the warm air generated by the electronic equipment in the data room. As the cool air warms from the heat of the electronic equipment, it flows through or under the equipment rack to the front of the equipment rack where the warm air rises. One or more ducts are positioned near or at the top of the equipment rack and, as the warm air enters the distal end of the return air ducts, it is transported through the proximal end of the return air ducts to the return intakes of the mini-split unit.

In other embodiments, the mini-split unit is positioned on the front side of the electronic equipment and a manifold is mounted to cover the bottom portion of the mini-split unit. Supply air ducts have proximal ends that connect to the manifold and distal ends that extend into the data room on the back side of the electronic equipment. Cool air flows through the supply air ducts to the area where the majority of the heat is exhausted from the electronic equipment. As the cool air warms from the heat of the electronic equipment, it flows through or under the equipment rack to the front of the equipment rack where the warm air rises to the return intake of the mini-split unit.

The foregoing has outlined rather broadly certain aspects of the present invention in order that the detailed description of the invention that follows may better be understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### DESCRIPTION OF THE DRAWINGS

For a more complete understanding of the present invention, and the advantages thereof, reference is now made to the following descriptions taken in conjunction with the accompanying drawings, in which:

FIG. 1A shows a perspective view of a typical mini-split system known in the art;

FIG. 1B shows a top view of the mini-split system shown in FIG. 1A;

FIG. 1C shows a side view of the mini-split system shown in FIG. 1A;

FIG. 2A shows a perspective view of one embodiment of the ducted mini-split system of the present invention;

FIG. 2B shows a top view of the ducted mini-split system shown in FIG. 2A;

FIG. 2C shows a side view of the ducted mini-split system shown in FIG. 2A;

FIG. 2D shows a detailed perspective view of the ducted mini-split system shown in FIG. 2A;

FIG. 3A shows a perspective view of another embodiment of the ducted mini-split system of the present invention;

FIG. 3B shows a top view of the ducted mini-split system shown in FIG. 3A;

FIG. 3C shows a side view of the ducted mini-split system shown in FIG. 3A;

FIG. 3D shows a detailed perspective view of the ducted mini-split system shown in FIG. 3A;

FIG. 4A shows a perspective view of yet another embodiment of the ducted mini-split system of the present invention;

FIG. 4B shows a top view of the ducted mini-split system shown in FIG. 4A;

FIG. 4C shows a side view of the ducted mini-split system shown in FIG. 4A; and

FIG. 4D shows a detailed perspective view of the ducted mini-split system shown in FIG. 4A.

### DETAILED DESCRIPTION OF THE INVENTION

The present invention is directed to improved methods and systems for, among other things, cooling data rooms. The configuration and use of the presently preferred embodiments are discussed in detail below. However, it should be appreciated that the present invention provides many applicable inventive concepts that can be embodied in a wide variety of contexts other than the cooling of data rooms. Accordingly, the specific embodiments discussed are merely illustrative of specific ways to make and use the invention, and do not limit the scope of the invention. In addition, the following terms shall have the associated meaning when used herein:

“data room” means any enclosure or room housing electronic equipment, including, for example, a small computer room, intermediate distribution frame (IDF) closet, or main distribution frame (MDF) closet; and

“electronic equipment” means servers, communication gear, storage equipment, routers, switches, firewalls and the like.

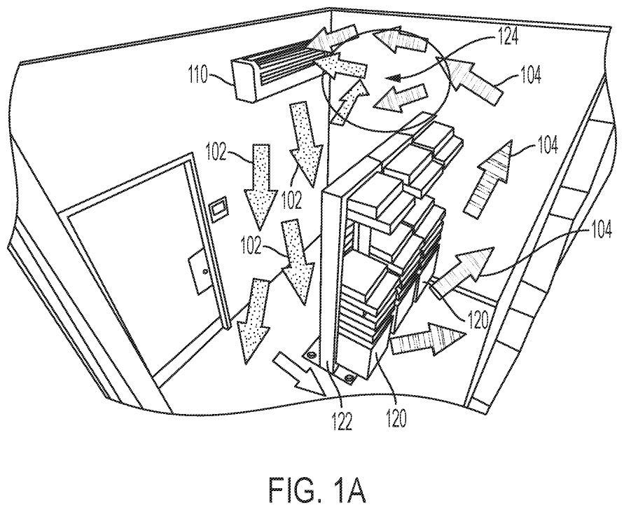

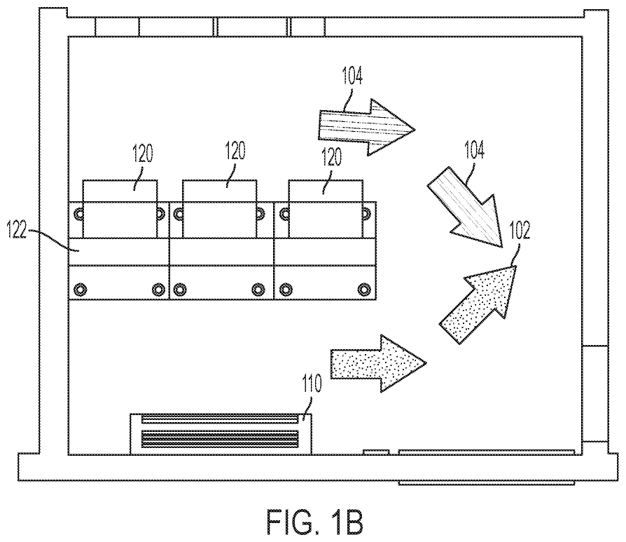

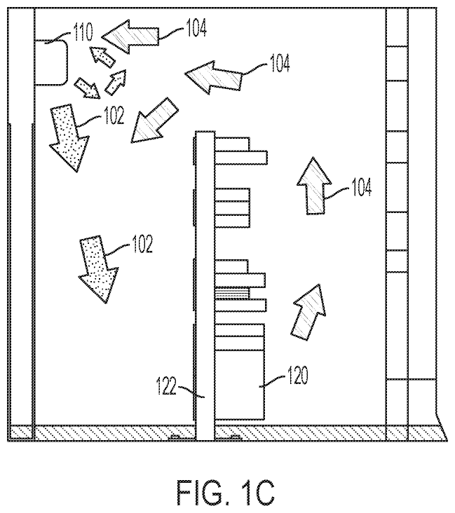

Referring now to FIGS. 1A-1C which shows a typical layout of electronic equipment 120 installed on racks 122 in a typical data room known in the art. The data room is cooled with a wall mounted HVAC mini-split unit 110 which delivers cool air 102 from the bottom of the unit 110 and takes in warm air 104 at the top of the unit 110. There are at least two issues associated with the type of unit shown here. First, if the unit 110 is placed in the cold aisle in front of the electronic equipment 120 and has a front-to-rear air flow, the unit's 110 return air supply is flooded with warm air which causes the unit 110 to be very inefficient. Also, the low velocity of the air in the area 124 above the equipment racks 122 also causes short cycling of the air delivered from the supply of the wall mounted HVAC unit 110 right back into the return. These issues greatly reduce the ability of the wall mounted unit 110 to cool a data room.

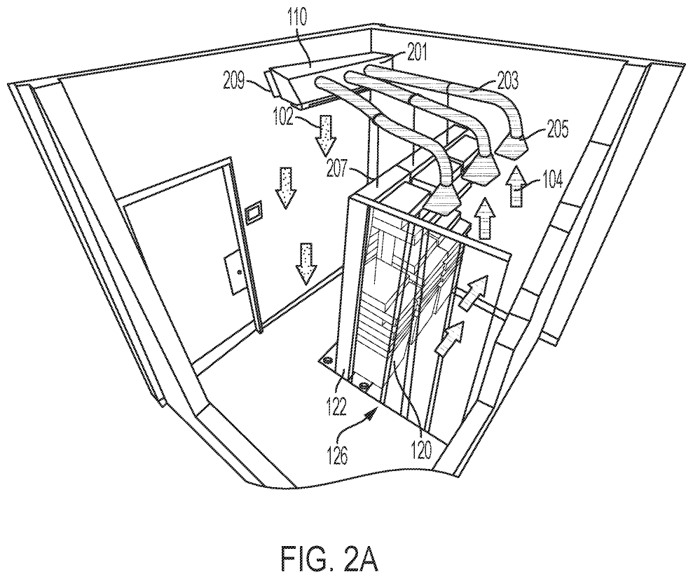

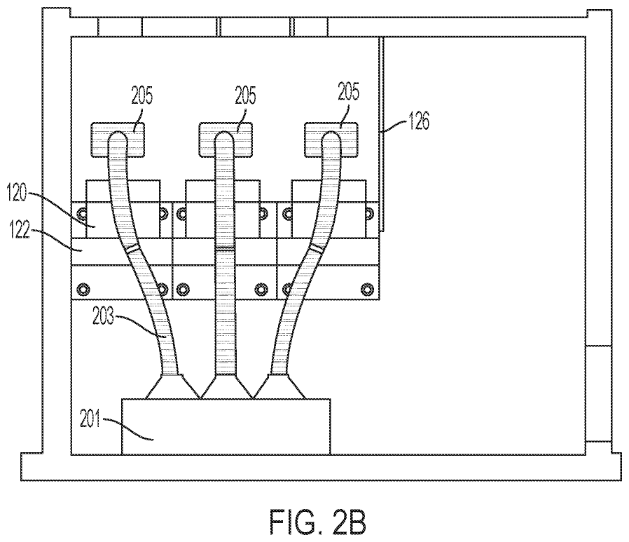

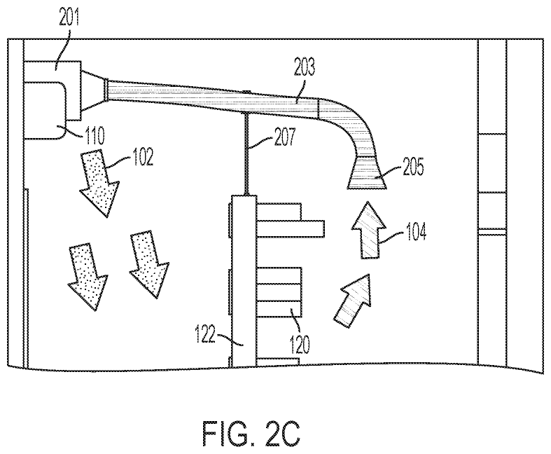

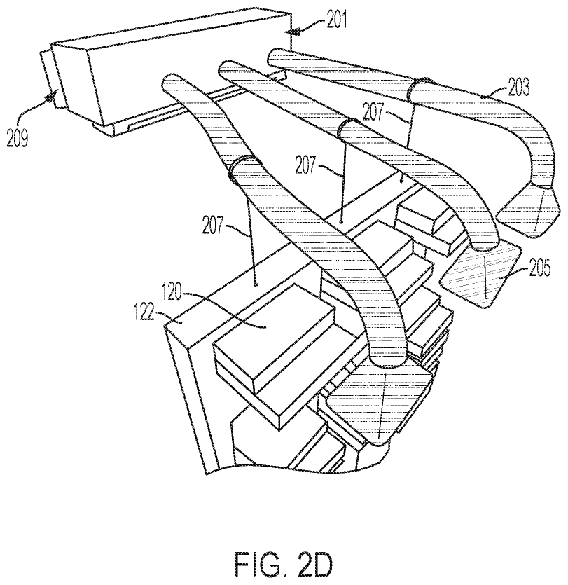

The embodiment of the present invention shown in FIGS. 2A-2D overcomes the deficiencies described above. A mini-split unit 110 has a supply air outlet and a return air intake. A manifold 201 covering the return air intake is mounted on the mini-split unit 110. Return air ducts 203 have proximal ends that connect to the manifold 201 and distal ends that extend into the data room. The mini-split unit 110 is positioned on the back, or warm, side of the equipment rack 120 where the majority of the heat is exhausted from the electronic equipment 120. Cool air 102 flows downward from the unit 110 behind the equipment rack 122, facilitated by the fact that cool air is lighter than warm air and, therefore sinks as warm air rises. As the cool air 102 warms from the heat of the electronic equipment 120, it flows through or under the equipment rack 122 to the front, or cool, side of the equipment rack 122 and the warm air 104 then rises. Two ducts 203 are positioned near or at the top of the equipment rack 122. As the warm air 104 enters the distal end of the return air ducts 203, it is transported through the proximal end of the return air ducts 203 to the return air intake of the mini-split unit 110.

In some embodiments, such as that shown in FIGS. 2A-2D, an air containment curtain 126 is included which serves as a physical barrier to aid in preventing warm air 104 from moving around the equipment rack 122 where it could mix with the descending cool air 102. While not shown in FIGS. 2A-2D, those skilled in the art will appreciate that if the equipment rack 122 was not positioned against the wall, a second containment curtain 126 could be configured adjacent to the opposite side of the equipment rack 122, thereby preventing warm air 104 from circulating around either side of the equipment rack 122.

Some embodiments of the present invention also include modifications of the distal end of the return air ducts 203 to facilitate the flow of warm air 104 into the return air ducts 203. For example, the distal ends of each return air duct 203 may be funnel-shaped as shown in FIGS. 2A-2D to allow warm air 104 to move easily into the return air ducts 203. The distal end of the return air ducts 203 may also be clipped or clamped to the equipment rack 122 or cable trays above the equipment rack 122 and, in some instances, the return air ducts 203 may each be positioned at an angle to optimize the capture of warm air 104.

In some embodiments a containment curtain may also cover the top of the equipment rack 122. In that instance, the containment curtain may have openings positioned therethrough through which the distal end of the return air ducts 203 are positioned.

Although two return air ducts 203 are shown in FIGS. 2A-2D, those skilled in the art will appreciate that one return air duct or more than two return air ducts may also be suitable depending on the size of the data room, air velocity, amount of electronic equipment being cooled and similar factors. In some embodiments, the return air ducts will be flexible, and in others, the return air ducts may be rigid.

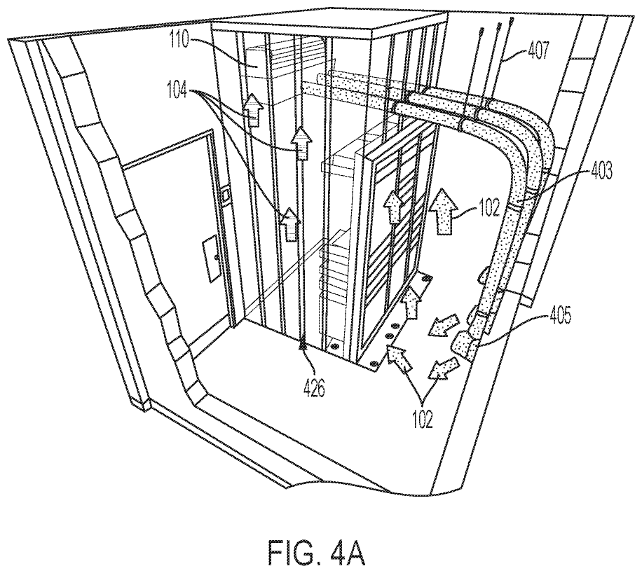

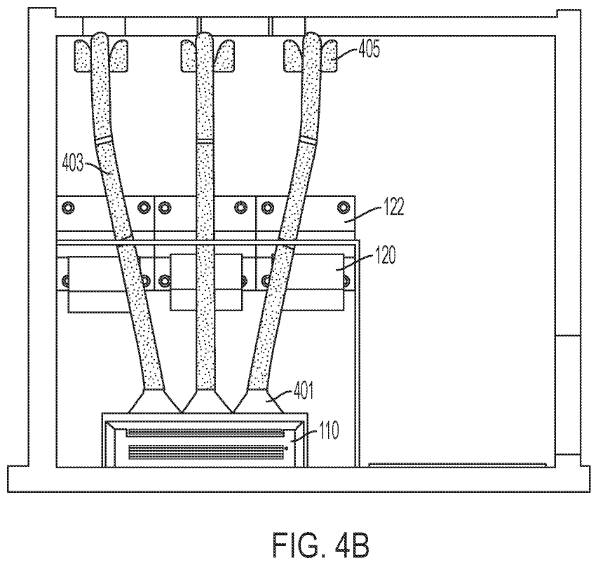

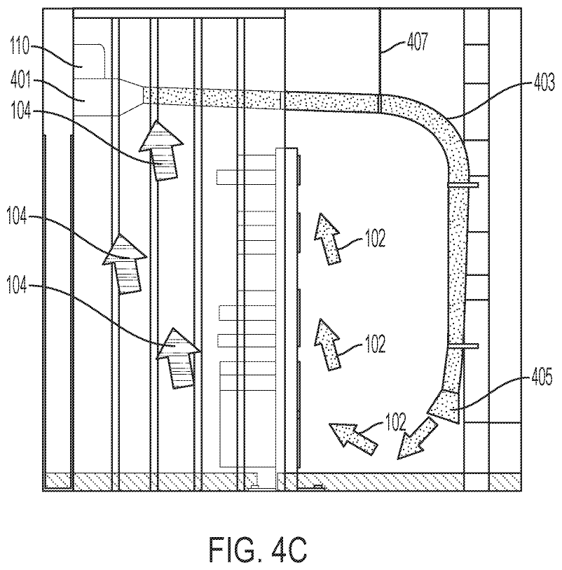

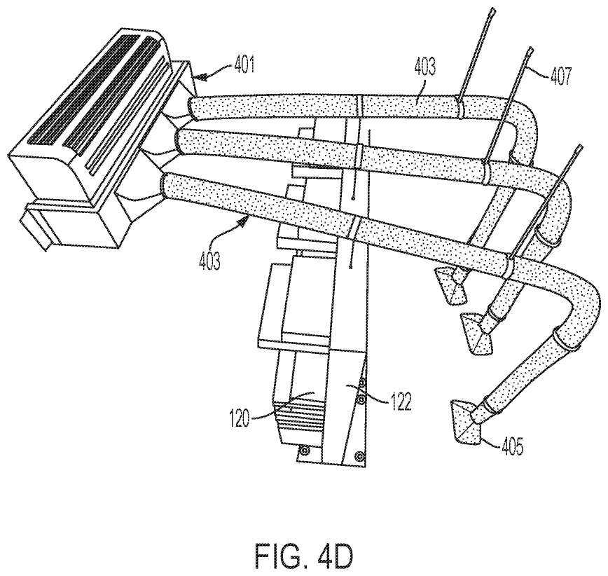

In addition, while the various embodiments shown herein may be retrofitted onto an existing HVAC mini-split unit, an alternative embodiment includes a mini-split unit with the ductwork manufactured as an integral part of the mini-split device. In that embodiment, it may be desirable to eliminate the manifold and simply design the body of the mini-spit unit to accommodate the proximal end of the return aid ducts, or in the embodiments described below and shown in FIGS. 4A-4D, the supply air ducts.

The embodiments of the invention described above allow the mini-split unit to move warm air more directly from the hot aisle of the room behind equipment rack 122 to the mini-split unit, thereby reducing air mixing, eliminating short cycling and increasing the efficiency of the mini-split unit in the data room.

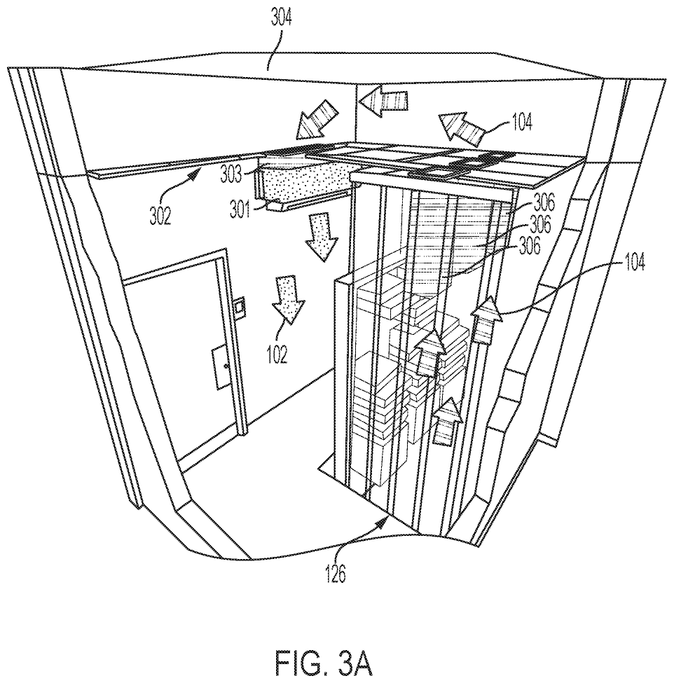

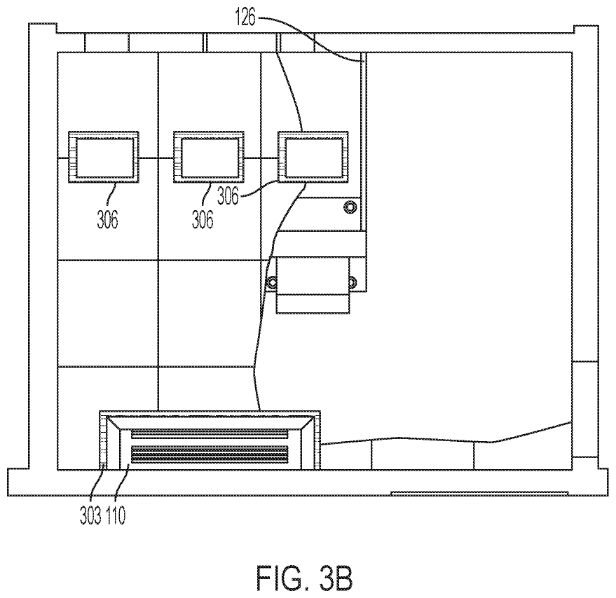

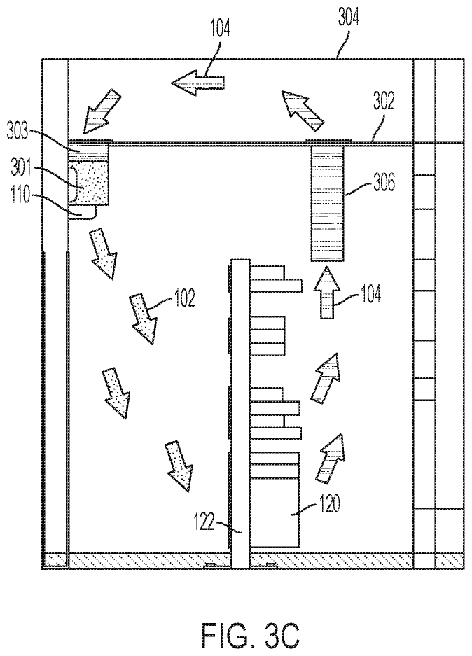

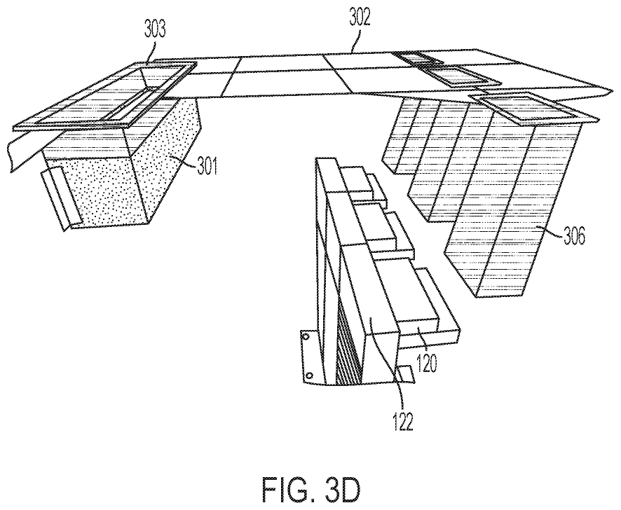

Another embodiment of the present invention shown in FIGS. 3A-3D also overcomes the deficiencies inherent in data room cooling systems known in the art. Again, a mini-split unit 110 having a supply air outlet and a return air intake is positioned in a data room and a manifold 301 covering the return air intake is mounted on the mini-split unit 110. A surround is positioned between the mini-split unit 110 and a suspended ceiling 302 in the data room and is configured to move air from the cavity between the suspended ceiling 301 and the actual ceiling 304 to the return air intake of the mini-split unit 110.

The mini-split unit 110 is positioned on the warm side of the equipment rack 120 where the majority of the heat is exhausted from the electronic equipment 120. Cool air 102 flows downward from the unit 110 behind the equipment rack 122. As the cool air 102 warms from the heat of the electronic equipment 120, it flows through or under the equipment rack 122 to the front of the equipment rack 122 and the warm air 104 then rises. In this embodiment, return air ducts 306 have upper ends that pass through the suspended ceiling 302 and lower ends that extend into the data room. As the warm air 104 enters the distal end of the return air ducts 306, it is transported through the cavity between the suspended ceiling 301 and the actual ceiling 304, through the surround 303, and on to the return air intake of the mini-split unit 110.

In essence, in this embodiment the cavity between the suspended ceiling 301 and the actual ceiling 304 becomes a return air plenum. Warm air 104 is drawn through the return air ducts 306 and into the cavity between the suspended ceiling 301 and the actual ceiling 304, thereby minimizing intermixing and maximizing the return air temperature.

Once again, an air containment curtain 126 may be utilized to serve as a physical barrier to aid in preventing warm air 104 from moving around the equipment rack 122 where it could mix with the descending cool air 102. While not shown in FIGS. 3A-3D, those skilled in the art will appreciate that if the equipment rack 122 was not positioned against the wall, a second containment curtain 126 could be configured adjacent to the opposite side of the equipment rack 122, thereby preventing warm air 104 from circulating around either side of the equipment rack 122.

Although three return air ducts 306 are shown in FIGS. 3A-3D, those skilled in the art will appreciate that one return air duct or more than two return air ducts may also be suitable depending on the size of the data room, air velocity, amount of electronic equipment being cooled and similar factors. In some embodiments, the return air ducts will be flexible, and in others, the return air ducts may be rigid.

Yet another embodiment of the present invention is shown in FIGS. 4A-4D. In this embodiment, the mini-split unit 110 having a supply air outlet and a return air intake is positioned on the front side of the electronic equipment 120. A manifold 401 covering the supply air outlet is mounted on the mini-split unit 110. Supply air ducts 403 have proximal ends that connect to the manifold 401 and distal ends that extend into the data room on the back side of the electronic equipment 120.

Cool air 102 flows from the supply air outlet through the supply air ducts 403 to the area where the majority of the heat is exhausted from the electronic equipment 120. As the cool air 102 warms from the heat of the electronic equipment 120, it flows through or under the equipment rack 122 to the front of the equipment rack 122 and the warm air 104 then rises to the return air intake of the mini-split unit 110.

In some embodiments, such as that shown in FIG. 4, an air containment curtain 126 is included which serves as a physical barrier to aid in preventing warm air 104 from moving around the equipment rack 122 where it could mix with the descending cool air 102. The air containment curtain may be supported by support posts anchored to the ceiling or some other overhead structure. While not shown in FIG. 4, those skilled in the art will appreciate that if the equipment rack 122 was not positioned against the wall, a second containment curtain 126 could be configured adjacent to the opposite side of the equipment rack 122, thereby preventing warm air 104 from circulating around either side of the equipment rack 122.

In some embodiments of the present invention modifications of the distal end of the supply air ducts 403 facilitate the flow of cool air 104 out of the supply air ducts 403 and into the data room. The distal end of the supply air ducts 403 may also be clipped or clamped to the equipment rack 122 or cable trays above the equipment rack 122 and, in some instances, the supply air ducts 403 may each be positioned at an angle to optimize the supply of cool air 102.

Although three supply air ducts 403 are shown in FIGS. 4A-4D, those skilled in the art will appreciate that less or more than three supply air ducts may also be suitable depending on the size of the data room, air velocity, amount of electronic equipment being cooled and similar factors. In some embodiments, the supply air ducts will be flexible, and in others, the supply air ducts may be rigid.

The embodiments of the invention described above allow the mini-split unit 110 to move cool air more directly to the cold aisle of the room to reduce air mixing, eliminate short cycling, and increase the capacity of the unit to cool electronic equipment within the data room.

While the present system has been disclosed according to the preferred embodiment of the invention, those of ordinary skill in the art will understand that other embodiments have also been enabled. Even though the foregoing discussion has focused on particular embodiments, it is understood that other configurations are contemplated. In particular, even though the expressions “in one embodiment” or “in another embodiment” are used herein, these phrases are meant to generally reference embodiment possibilities and are not intended to limit the invention to those particular embodiment configurations. These terms may reference the same or different embodiments, and unless indicated otherwise, are combinable into aggregate embodiments. The terms “a”, “an” and “the” mean “one or more” unless expressly specified otherwise. The term “connected” means “communicatively connected” unless otherwise defined.

When a single embodiment is described herein, it will be readily apparent that more than one embodiment may be used in place of a single embodiment. Similarly, where more than one embodiment is described herein, it will be readily apparent that a single embodiment may be substituted for that one device.

In light of the wide variety of methods for configuring mini-split HVAC systems known in the art, the detailed embodiments are intended to be illustrative only and should not be taken as limiting the scope of the invention. Rather, what is claimed as the invention is all such modifications as may come within the spirit and scope of the following claims and equivalents thereto.

None of the description in this specification should be read as implying that any particular element, step or function is an essential element which must be included in the claim scope. The scope of the patented subject matter is defined only by the allowed claims and their equivalents. Unless explicitly recited, other aspects of the present invention as described in this specification do not limit the scope of the claims.

1. A ducted HVAC mini-split system, comprising:
a data room having at least one equipment rack positioned therein, the equipment rack having a warm side into which heat from electronic equipment on the equipment rack is exhausted, and a cool side opposite the warm side;
a mini-split unit having a supply air outlet and a return air intake, the mini-split unit being positioned in the data room and configured with the supply air outlet directed to the warm side of the equipment rack;
a manifold covering the return air intake; and
one or more return air ducts, each having a proximal end and a distal end, the distal end positioned on the cool side of the equipment rack and the proximal end being connected to the manifold so that air entering the distal end of the return air duct, through the manifold, and into the return air intake.

2. The ducted HVAC mini-split system of claim 1, wherein one end of the equipment rack is positioned against a wall and wherein a containment curtain is positioned adjacent to the one end of the equipment rack, thereby preventing air on the warm side from mixing with air on the cool side.

3. The ducted HVAC mini-split system of claim 1, wherein containment curtains are positioned adjacent to each end of the equipment rack, thereby preventing air on the warm side from mixing with air on the cool side.

4. The ducted HVAC mini-split system of claim 1, wherein containment curtains are positioned adjacent to each end of the equipment rack and a containment curtain is positioned above the equipment rack, the containment curtain positioned above the equipment rack having openings therethrough through which the distal ends of the one or more ducts protrude, thereby preventing air on the warm side from mixing with air on the cool side.

5. The ducted HVAC mini-split system of claim 1, wherein the distal end of each of the one or more return air ducts is funnel shaped to facilitate entry of air into the return air duct.

6. A ducted HVAC mini-split system, comprising:
a data room having at least one equipment rack positioned therein, the equipment rack having a warm side into which heat from electronic equipment on the equipment rack is exhausted, and a cool side opposite the warm side;
a mini-split unit having a supply air outlet and a return air intake, the mini-split unit being positioned in the data room and configured with the supply air outlet directed to the warm side of the equipment rack;
a manifold covering the return air intake;
a surround for conveyance of air positioned between the manifold and a suspended ceiling; and
one or more return air ducts, each having a proximal end and a distal end, the distal end positioned on the cool side of the equipment rack and the proximal end being connected to suspended ceiling so that air entering the distal end of the duct passes therethrough and exits the proximal end of the return air duct, into a cavity between the suspended ceiling and an actual ceiling of the data room and then continues through the through the surround, through the manifold and into the return air intake.

7. The ducted HVAC mini-split system of claim 6, wherein one end of the equipment rack is positioned against a wall and wherein a containment curtain is positioned adjacent to the one end of the equipment rack, thereby prevent air on the warm side from mixing with air on the cool side.

8. The ducted HVAC mini-split system of claim 6, wherein containment curtains are positioned adjacent to each end of the equipment rack, thereby preventing air on the warm side from mixing with air on the cool side.

9. The ducted HVAC mini-split system of claim 6, wherein the distal end of each of the one or more return air ducts is funnel shaped to facilitate entry of air into the return air duct.

10. The ducted HVAC mini-split system comprising:
a data room having at least one equipment rack positioned therein, the equipment rack having a warm side into which heat from electronic equipment on the equipment rack is exhausted, and a cool side opposite the warm side;
a mini-split unit having a supply air outlet and a return air intake, the mini-split unit being positioned in the data room and configured with the return air intake positioned on the warm side of the equipment rack;
a manifold covering the supply air outlet; and
one or more supply air ducts, each having a proximal end and a distal end, the distal end positioned on the cool side of the equipment rack and the proximal end being connected to the manifold so that supply air entering the proximal end of the supply air duct passes therethrough and exits the distal end of the supply air duct on the cool side.

11. The ducted HVAC mini-split system of claim 10, wherein one end of the equipment rack is positioned against a wall and wherein a containment curtain is positioned adjacent to one end of the equipment rack thereby preventing air on the warm side from mixing with air on the cool side.

12. The ducted HVAC mini-split system of claim 10, wherein containment curtains are positioned adjacent to each end of the equipment rack, thereby preventing air one the warm side from mixing with air on the cool side.

13. The ducted HVAC mini-split system of claim 10, wherein the distal end of each of the one or more supply air ducts is funnel shaped to facilitate egress of air out of the supply air duct.
